(19) United States
(12) Patent Application Publication
(10) Pub. No.: US 2016/0216100 A1
(43) Pub. Date: Jul. 28, 2016

(54) APPARATUS FOR MEASURING CONTAMINATION OF PLASMA GENERATING DEVICE

(71) Applicant: Samsung Display Co., Ltd., Yongin-city (KR)

(72) Inventors: Jihun Kim, Yongin-city (KR); Dongil Kim, Yongin-city (KR)

(21) Appl. No.: 14/799,810

(22) Filed: Jul. 15, 2015

(30) Foreign Application Priority Data
Jan. 22, 2015 (KR) 10-2015-0010551

(51) Int. Cl. G01B 7/06; C23C 16/52; C23C 16/50

(52) U.S. Cl. CPC G01B 7/085; C23C 16/50; C23C 16/52

(57) ABSTRACT

An apparatus for measuring contamination of a plasma generating includes: a chamber; a susceptor provided in the chamber and on which a substrate is mounted; a plasma generator configured to generate plasma in the chamber; an inner jacket provided in the chamber and surrounding a space where the plasma is generated; a V-I probe electrically connected to the inner jacket and configured to detect a phase difference between a voltage and a current; a power supply unit configured to supply the voltage to the inner jacket through a blocking capacitor; and a monitor connected to the V-I probe and configured to store and display measurement data. A thickness of a contamination layer on a surface of the inner jacket is determined by analyzing a signal obtained by supplying the voltage to the inner jacket.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

This application claims the benefit of Korean Patent Application No. 10-2015-0010551, filed on Jan. 22, 2015, in the Korean Intellectual Property Office, the disclosure of which is incorporated herein in its entirety by reference.

### BACKGROUND

1. Field

One or more embodiments relate to an apparatus for measuring contamination of a plasma generating device.

2. Description of the Related Technology

Generally, a plasma generating device is applied to various fields where processes such as an etching process, a sputtering process, or a deposition process, among others, are used. A plasma generating device used for an etching process may be a capacitively coupled plasma (CCP) device or an inductively coupled plasma (ICP) device. A plasma generating device used for a deposition process may be a chemical vapor deposition (CVD) device, a plasma enhanced CVD (PECVD) device, or a physical vapor deposition (PVD) device.

The CVD device may be used to form a thin film of an organic light-emitting display apparatus or a liquid crystal display, for example, an insulating film, a metal film, or an organic film. The PECVD device may be used to deposit a thin film on a substrate by generating a reaction in an injection gas by supplying plasma.

Various contamination sources may exist in a chamber of the plasma generating device during or after plasma processing. In this regard, a thickness change of a contamination layer on an inner wall of the chamber may be monitored and a cleaning process may be performed according to the thickness change.

### SUMMARY OF CERTAIN INVENTIVE ASPECTS

One or more embodiments include an apparatus for measuring contamination of a plasma generating device.

Additional aspects will be set forth in part in the description which follows and, in part, will be apparent from the description, or may be learned by practice of the presented embodiments.

According to one or more embodiments, an apparatus for measuring contamination of a plasma generating device, the apparatus includes: a chamber; a susceptor provided in the chamber and on which a substrate is mounted; a plasma generator configured to generate plasma in the chamber; an inner jacket provided in the chamber and surrounding a space where the plasma is generated; a V-I probe electrically connected to the inner jacket and is configured to detect a phase difference between a voltage and a current; a power supply unit configured to supply the voltage to the inner jacket through a blocking capacitor; and a monitor connected to the V-I probe and is configured to store and display measurement data, wherein a thickness of a contamination layer on a surface of the inner jacket is determined by analyzing a signal obtained by supplying the voltage to the inner jacket.

The voltage may be supplied from the power supply unit to the inner jacket through the chamber via at least one feedthrough.

The blocking capacitor may be disposed between the power supply unit and the chamber.

The feedthrough may be connected to at least one region of an outer surface of the inner jacket and may be configured to monitor a contamination level according to locations thereof in the chamber.

The inner jacket may be spaced apart from an inner wall of the chamber.

The inner jacket may have a wall shape that surrounds the space where the plasma is generated.

The inner jacket may be combined with the chamber, thereby forming a double wall.

The inner jacket may include a metal.

The inner jacket may include a metal layer and an insulating layer coated on an outer surface of the metal layer.

The inner jacket may include an anodized metal.

According to one or more embodiments, a method for measuring contamination of a plasma generating device in the apparatus includes: generating plasma in the chamber; supplying the voltage to the inner jacket through a blocking capacitor; and determining a thickness of the contamination layer on the surface of the inner jacket by analyzing a signal obtained by supplying the voltage to the inner jacket.

A contamination level of the inner jacket may be monitored in real-time.

The contamination level may be monitored without interrupting a vacuum state of the chamber.

A radio frequency (RF) voltage may be supplied to the inner jacket.

The power supply unit may supply an RF signal in a range from about 1 to about 100 KHz and in a range from about 1 to about 10 V.

The signal analysis may be performed by analyzing a phase difference between the RF voltage and an RF current flowing by the RF voltage, by using the V-I probe.

The thickness of the contamination layer may be calculated based on a capacitance of the contamination layer, wherein the capacitance may be calculated based on a phase difference between the RF voltage and an RF current flowing due to the RF voltage.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic diagram of a plasma generating device according to an embodiment;

FIG. 2 illustrates a graph of a phase difference vs. a thickness of a contamination layer according to experiments performed by the applicant;

FIG. 3 is a schematic plan view of a V-I probe connected to an inner jacket, according to another embodiment;

FIG. 4 is a schematic plan view of a V-I probe connected to an inner jacket, according to an embodiment;

FIG. 5 is a perspective view of a flexible display apparatus in a spread state according to an embodiment;

FIG. 6 is a perspective view of the flexible display apparatus in a rolled state according to an embodiment; and

FIG. 7 is a cross-sectional view of a sub-pixel of a flexible display apparatus, according to an embodiment.

### DETAILED DESCRIPTION OF CERTAIN INVENTIVE EMBODIMENTS

As the disclosure allows for various changes and numerous embodiments, certain embodiments will be illustrated in drawings and described in detail in the written description. However, this is not intended to limit the embodiments to particular modes of practice, and it will to be appreciated that all changes, equivalents, and substitutes that do not depart from the spirit and technical scope of the embodiments are encompassed in the embodiments. In the description of the embodiments, certain detailed explanations of related art are omitted when it is deemed that they may unnecessarily obscure the essence of the embodiments.

Expressions such as “at least one of”, when preceding a list of elements, modify the entire list of elements and do not modify the individual elements of the list.

While such terms as “first”, “second”, and the like, may be used to describe various components, such components must not be limited to the above terms. The above terms are used only to distinguish one component from another.

The terms used in the present specification are merely used to describe certain embodiments, and are not intended to limit the embodiments. An expression used in the singular encompasses the expression in the plural, unless it has a clearly different meaning in the context. In the present specification, it is to be understood that terms such as “including” or “having”, and the like, are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

An apparatus for measuring contamination of a plasma generating device according to one or more embodiments will be described below in more detail with reference to the accompanying drawings. Those components that are the same or are in correspondence are rendered the same reference numeral regardless of the figure number, and redundant explanations are omitted.

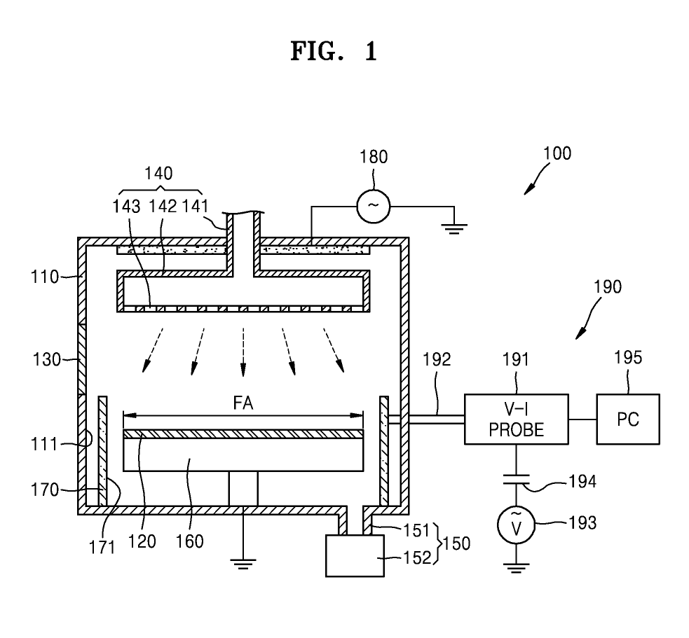

FIG. 1 is a schematic diagram of a plasma generating device 100 according to an embodiment.

Referring to FIG. 1, the plasma generating device 100 may include a chamber 110. The chamber 110 provides a space for isolating an external environment and a reaction space from each other. An inlet 130 for a transfer device (not shown) that transfers a substrate 120 into the chamber 110 may be provided at one side of the chamber 110. A location and a size of the inlet 130 are not limited.

A plasma generator that generates plasma may be provided in the chamber 110. According to one embodiment, the plasma generator is not limited as long as plasma is generated in the chamber 110.

A gas injector 140 may be disposed at an upper side of the chamber 110, and a gas discharger 150 may be disposed at a lower side of the chamber 110. According to one embodiment, the gas injector 140 includes a gas injection hole 141 and a shower head 142 connected to the gas injection hole 141. A gas may be injected into the chamber 110 through the gas injection hole 141, and the injected gas may be uniformly sprayed on a film-forming area FA through the shower head 142.

The shower head 142 includes a plurality of nozzles 143 that are spaced apart from each other below the shower head 142. The gas is uniformly distributed on the film-forming area FA through the nozzles 143, and thus uniformity of a thin film, such as an organic film, deposited on the substrate 120 may be increased. The nozzles 143 do not have to be spaced apart from each other at regular intervals, and the gas injector 140 may not include the shower head 142.

The gas discharger 150 includes an exhaust opening 151 that discharges the gas to the outside the chamber 110, and a vacuum pump 152 that is connected to the exhaust opening 151 to maintain a certain vacuum level in the chamber 110.

The substrate 120 may be mounted on a susceptor 160. A thin film, such as an organic film, may be formed on the substrate 120 according to a reaction of the gas injected to the chamber 110. According to one embodiment, a pattern mask (not shown) may be disposed on the substrate 120.

An inner jacket 170 that surrounds a space where plasma is generated may be provided in the chamber 110. The inner jacket 170 may be provided at a side wall 111 of the chamber 110, and protect the side wall 111 of the chamber 110.

The inner jacket 170 may surround the side wall 111 of the chamber 110. The inner jacket 170 may form a double wall together with the chamber 110. According to one embodiment, the inner jacket 170 may be spaced apart from the side wall 111 of the chamber 110, but a location of the inner jacket 170 is not limited thereto as long as the inner jacket 170 is provided in the chamber 110, for example, the inner jacket 170 may contact the side wall 111 of the chamber 110.

The inner jacket 170 may include a metal. According to one embodiment, the inner jacket 170 may include a metal layer and an insulating layer coated on an outer surface of the metal layer. According to another embodiment, the inner jacket 170 may include an anodized metal.

The inner jacket 170 may be separated from the chamber 110 and cleaned.

A deposition process of the plasma generating device 100 having such a structure is as follows.

A material to be deposited on the substrate 120 through the gas injection hole 141 is injected to the shower head 142. The shower head 142 uniformly sprays the gas injected through the gas injection hole 141 into the chamber 110.

A high frequency supply unit 180 applies a high frequency for decomposing the gas into plasma particles into the chamber 110. Then, the plasma particles are deposited on the substrate 120.

A reaction gas including plasma particles that are used to deposit a thin film is discharged through the gas discharger 150.

Through such a deposition process, a thin film, such as an organic film, may be formed on a desired region on the substrate 120.

During or after a plasma processing, the inside of the chamber 110 may be contaminated. For example, contaminants may be adhered to an inner wall 171 of the inner jacket 170 surrounding the space where plasma is generated.

A contamination level of the inner wall 171 of the inner jacket 170 during or after the plasma processing needs to be monitored in real-time without breaking a vacuum of the chamber 110.

The plasma generating device 100 may include a system 190 for detecting a contamination layer in the chamber 110.

The system 190 includes a V-I probe 191, a power supply unit 193, a blocking capacitor 194, and a monitor 195.

The V-I probe 191 may be electrically connected to the inner jacket 170. The V-I probe 191 may detect a phase difference between a voltage V and a current I flowing through the inner jacket 170.

The V-I probe 191 may be connected to the inner jacket 170 through a feedthrough 192. The feedthrough 192 may be electrically connected to the inner jacket 170. The feedthrough 192 may be connected to at least one region of the inner jacket 170. According to one embodiment, the feedthrough 192 may be connected in a vacuum state.

The power supply unit 193 for supplying a voltage through the blocking capacitor 194 may be connected to the inner jacket 170. The voltage supplied from the power supply unit 193 may be supplied to the inner jacket 170 through the chamber 110, wherein the blocking capacitor 194 is disposed between the power supply unit 193 and the chamber 110.

According to one embodiment, a radio frequency (RF) voltage may be supplied to the inner jacket 170. For example, an RF signal supplied from the power supply unit 193 may be in a range from about 1 to about 100 KHz and in a range from about 1 to about 10 V. Plasma may be adversely affected when the RF signal is outside the above ranges.

The monitor 195 displaying measurement data may be connected to the V-I probe 191. In some embodiments, the monitor may include a personal computer or other computing device including memory and storage.

The system 190 may measure a thickness of a contamination layer on the inner wall 171 of the inner jacket 170 by analyzing a signal obtained by supplying a voltage to the inner jacket 170. The signal analysis is performed by analyzing a phase difference between the RF voltage and an RF current flowing by the RF voltage, by using the V-I probe 191.

The thickness of the contamination layer on the inner wall 171 of the inner jacket 170 may be calculated based on capacitance of the contamination layer, wherein the capacitance is calculated from the phase difference between the RF voltage and the RF current.

The system 190 may measure the thickness of the contamination layer on the inner jacket 170 as follows.

The RF signal in the range from about 1 to about 100 KHz and in the range from about 1 to about 10 V supplied from the power supply unit 193 is applied to the inner jacket 170 through the blocking capacitor 194.

When the RF signal is applied to the inner jacket 170, the V-I probe 191 detects the phase difference between the RF voltage and the RF current flowing through the inner jacket 170.

When the thickness of the contamination layer on the inner wall 171 of the inner jacket 170 changes, the phase difference is changed. Thus, by analyzing the phase difference, a change of the thickness of the contamination layer may be monitored in real-time.

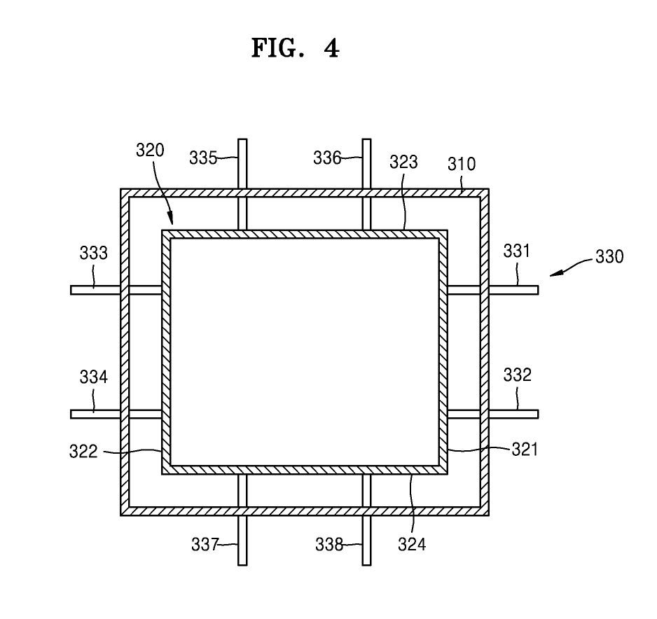

Table 1 shows a phase difference according to a thickness of a contamination layer based on an experiment of the applicant, and FIG. 4 is a graph showing the phase difference according to the thickness of the contamination layer of Table 1.

TABLE 1

| Thickness of | |
|---|---|
| contamination Layer | |
| (um) | Phase Difference (θ°) |
| 1.0 | 65.6° |
| 2.0 | 68.4° |
| 3.0 | 70.6° |
| 4.0 | 72.4° |
| 5.0 | 73.9° |
| 6.0 | 75.2° |
| 7.0 | 76.3° |
| 8.0 | 77.3° |
| 9.0 | 78.1° |
| 10.0 | 78.8° |

The inner jacket 170 includes an anodized metal, and a thickness of an anodized layer is about 30 um and relative permittivity of the anodized layer is about 10.

Next, a contamination layer having the same thickness as the anodized layer is formed on the inner wall 171 of the inner jacket 170, and relative permittivity of the contamination layer is 2.

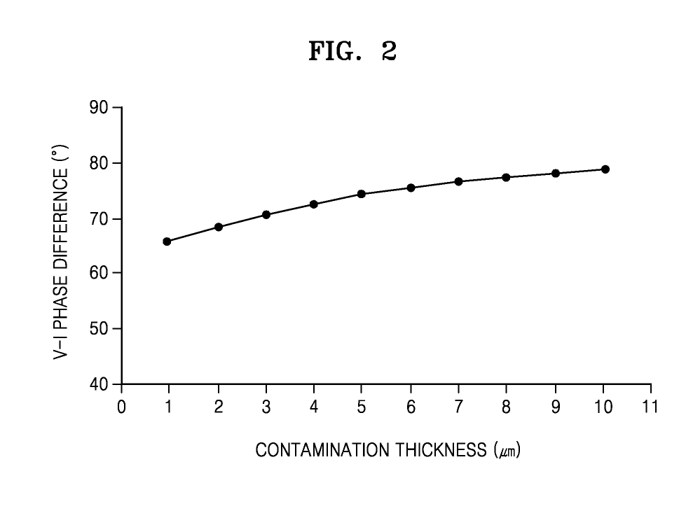

Referring to Table 1 and FIG. 2, when the thickness of the contamination layer increases to 1, 2, 3, 4, 5, 6, 7, 8, 9, and 10 um, the phase difference between the RF voltage and the RF current increases respectively to 65.6°, 68.4°, 70.6°, 72.4°, 73.9°, 75.2°, 76.3°, 77.3°, 78.1°, and 78.8°. As such, by monitoring the phase difference, the thickness of the contamination layer may be calculated.

The contamination layer may be monitored according to locations in the chamber 110.

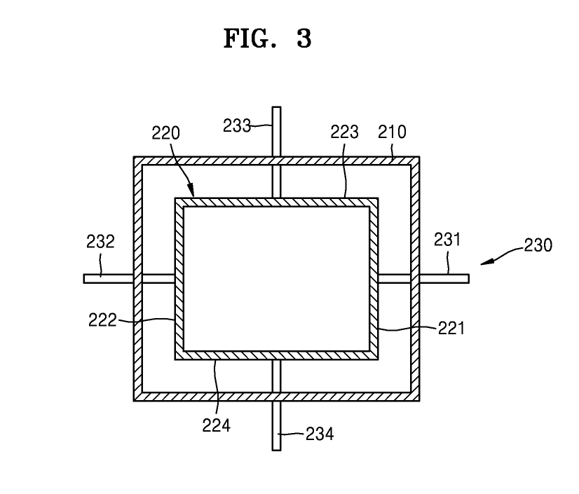

For example, as shown in FIG. 3, an inner jacket 220 surrounding a plasma space while being spaced apart from the plasma space may be provided in a chamber 210. A plurality of feedthroughs 230 may be connected to the inner jacket 220.

The inner jacket 220 has a rectangular shape, and includes first and second surfaces 221 and 222, which face each other along a first direction, and third and fourth surfaces 223 and 224, which face each other in another direction crossing the first direction.

First through fourth feedthroughs 231 through 234 may be respectively connected to the first through fourth surfaces 221 through 224 through the chamber 210.

As such, a contamination layer may be monitored in four zones of the inner jacket 220.

Referring to FIG. 4, an inner jacket 320 may be provided in a chamber 310. A plurality of feedthroughs 330 may be connected to the inner jacket 320.

The inner jacket 320 has a rectangular shape, and includes first and second surfaces 321 and 322, which face each other along a first direction, and third and fourth surfaces 323 and 324, which face each other in another direction crossing the first direction.

Two feedthroughs may be connected to each of the first through fourth surfaces 321 through 324. In detail, first and second feedthroughs 331 and 332 may be connected to the first surface 321, third and fourth feedthroughs 333 and 334 may be connected to the second surface 322, fifth and sixth feedthroughs 335 and 336 may be connected to the third surface 323, and seventh and eighth feedthroughs 337 and 338 may be connected to the fourth surface 324.

As such, a contamination layer may be monitored in eight zones of the inner jacket 330.

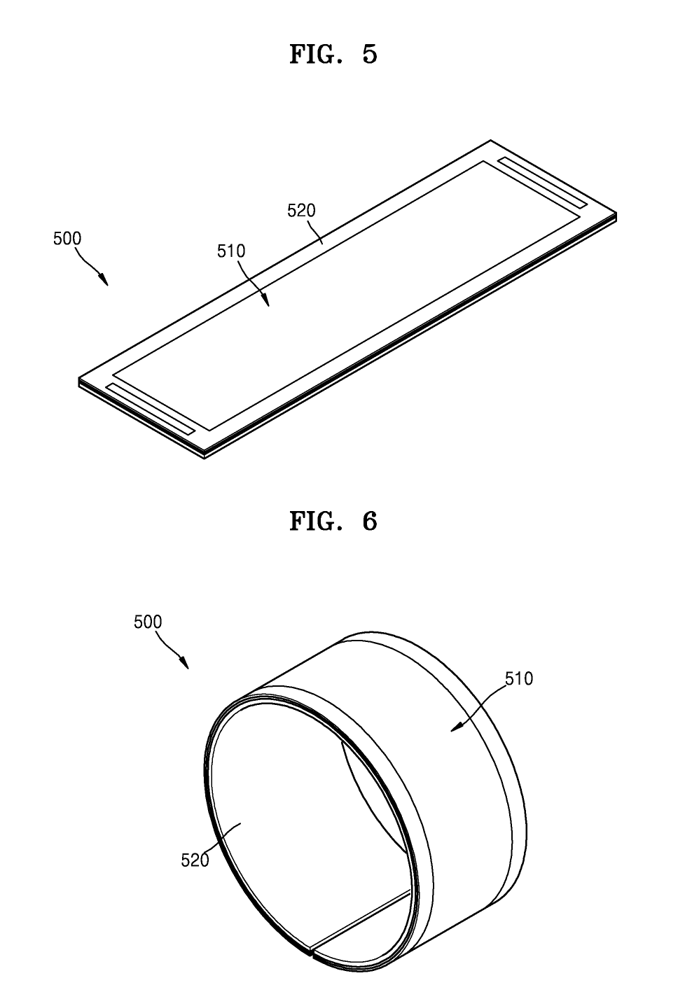

FIGS. 5 and 6 are views for describing a flexible display apparatus 500 including at least one of an insulating film, a metal film, and an organic film, which is formed by using the plasma generating device 100 of FIG. 1.

FIG. 5 is a perspective view of the flexible display apparatus 500 in a spread state according to an embodiment, and FIG. 6 is a perspective view of the flexible display apparatus 500 in a rolled state according to an embodiment.

Referring to FIGS. 5 and 6, the flexible display apparatus 500 includes a flexible display panel 510 displaying an image, and a flexible case 520 accommodating the flexible display panel 510. The flexible display panel 510 not only includes a device for realizing a screen, but also includes various films, such as a touch screen, a polarization plate, and a window cover. A user may view an image in various angles, for example, when the flexible display apparatus 500 is spread or rolled.

According to one embodiment, the flexible display apparatus 500 is an organic light-emitting display device having flexibility, but alternatively, the flexible display apparatus 500 may be any one of various flexible display apparatuses, such as a liquid crystal display apparatus, a field emission display apparatus, and an electronic paper display apparatus.

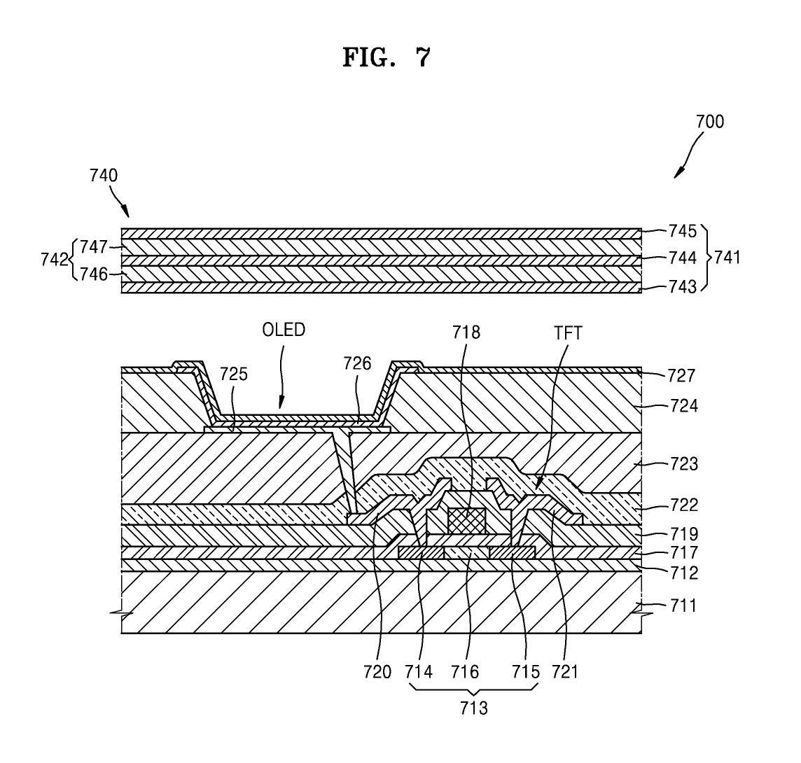

FIG. 7 is a cross-sectional view of a sub-pixel of a flexible display apparatus 700, according to an embodiment.

Referring to FIG. 7, the flexible display apparatus 700 includes a flexible substrate 711 and an encapsulation film 740 facing the flexible substrate 711.

The flexible substrate 711 may include a flexible insulating material.

The flexible substrate 711 may be a polymer substrate including polyimide (PI), polycarbonate (PC), polyethersulphone (PES), polyethylene terephthalate (PET), polyethylenenaphthalate (PEN), polyarylate (PAR), or fiber glass reinforced plastic (FRP). According to one embodiment, the flexible substrate 711 may be flexible glass substrate.

The flexible substrate 711 may be transparent, semi-transparent, or opaque.

A barrier film 712 may be formed on the flexible substrate 711. The barrier film 712 may entirely cover a top surface of the flexible substrate 711.

The barrier film 712 may include inorganic materials, such as, for example, silicon oxide (SiOx), silicon nitride (SiNx), silicon oxynitride (SiOxNy), aluminum oxide (AlOx), and aluminum nitride (AlOxNy), and organic materials, such as, for example, acryl, PI, and polyester.

The barrier film 712 may include a single film or a multilayer film.

The barrier film 712 blocks oxygen and moisture, and flattens a top surface of the flexible substrate 711.

A thin-film transistor TFT may be formed on the barrier film 712.

According to one embodiment, the thin-film transistor TFT is a top gate transistor, but alternatively, the thin-film transistor TFT may be another type, such as a bottom gate transistor.

A semiconductor active layer 713 may be formed on the barrier film 712.

The semiconductor active layer 713 includes a source region 714 and a drain region 715 by doping N-type impurity ions or P-type impurity ions. A channel region 716 that is not doped with an impurity is disposed between the source and drain regions 714 and 715.

The semiconductor active layer 713 may include an inorganic semiconductor such as, for example, polysilicon, an organic semiconductor, or amorphous silicon.

According to one embodiment, the semiconductor active layer 713 may include an oxide semiconductor. The oxide semiconductor includes an oxide of a material selected from 4, 12, 13, and 14-group metal elements, such as zinc (Zn), indium (In), gallium (Ga), tin (Sn), cadmium (Cd), germanium (Ge), and hafnium (Hf), and a combination thereof.

A gate insulating film 717 may be deposited on the semiconductor active layer 713. The gate insulating film 717 may be an inorganic film formed of, for example, silicon oxide, silicon nitride, or metal oxide. The gate insulating film 717 may include a single layer or a multilayer.

A gate electrode 718 may be formed on the gate insulating film 717. The gate electrode 718 includes a single layer or a multilayer including gold (Au), silver (Ag), copper (Cu), nickel (Ni), platinum (Pt), palladium (Pd), aluminum (Al), molybdenum (Mo), or chromium (Cr). According to one embodiment, the gate electrode 718 may include an alloy, such as Al:Nd or Mo:W, for example.

An interlayer insulating film 719 may be formed on the gate electrode 718. The interlayer insulating film 719 may include an inorganic material, such as, for example, silicon oxide or silicon nitride. According to one embodiment, the interlayer insulating film 719 includes an organic material.

A source electrode 720 and a drain electrode 721 may be formed on the interlayer insulating film 719. Contact holes are formed by removing parts of the gate insulating film 717 and interlayer insulating film 719, and the source electrode 720 may be electrically connected to the source region 714, and the drain electrode 721 may be electrically connected to the drain region 715, through the contact holes.

A passivation film 722 may be formed on the source and drain electrodes 720 and 721. The passivation film 722 may include an inorganic material, such as, for example, silicon oxide or silicon nitride, or an organic material.

A planarization film 723 may be formed on the passivation film 722. The planarization film 723 may include an organic material, such as, for example, acryl, PI, or benzocyclobutene (BCB).

One of the passivation film 722 and the planarization film 723 may be omitted in some embodiments.

The thin-film transistor TFT may be electrically connected to an organic light-emitting display device OLED.

The organic light-emitting display device OLED may be formed on the planarization film 723. The organic light-emitting display device OLED includes a first electrode 725, an intermediate layer 726, and a second electrode 727.

The first electrode 725 operates as an anode, and may include any one of various conductive materials. The first electrode 725 may be a transparent electrode or a reflective electrode. For example, when the first electrode 725 is a transparent electrode, the first electrode 725 includes a transparent conductive film including indium tin oxide (ITO), indium zinc oxide (IZO), zinc oxide (ZnO), or indium oxide (In₂O₃). When the first electrode 725 is a reflective electrode, the first electrode 725 includes a reflective film including Ag, Mg, Al, Pt, Pd, Au, Ni, Nd, Ir, Cr, or a compound thereof, and a transparent conductive film formed of ITO, IZO, ZnO, or In₂O₃, on the reflective film.

A pixel-defining film 724 may be formed on the planarization film 723. The pixel-defining film 724 covers a part of the first electrode 725. The pixel-defining film 724 limits an emission region of each sub-pixel by surrounding an edge of the first electrode 725. The first electrode 725 may be patterned per sub-pixel.

The pixel-defining film 724 may include an organic film or an inorganic film. For example, the pixel-defining film 724 may include an organic material, such as, for example, PI, polyamide, BCB, acryl resin, or phenol resin, or an inorganic material, such as, for example, silicon nitride.

The pixel-defining film 724 may be a single film or a multilayer film.

The intermediate layer 726 may be formed in a region on the first electrode 725, which is exposed by the pixel-defining film 724. According to one embodiment, the intermediate layer 726 may be formed via a deposition process.

The intermediate layer 726 may include an organic emission layer. Alternatively, the intermediate layer 726 may include the organic emission layer and further include at least one of a hole injection layer (HIL), a hole transport layer (HTL), an electron transport layer (ETL), or an electron injection layer (EIL). Alternatively, the intermediate layer 726 may include the organic emission layer, and further include other various functional layers.

Holes and electrons injected respectively from the first and second electrodes 725 and 727 may combine in the organic emission layer, thereby generating light in a certain color.

The second electrode 727 may be formed on the intermediate layer 726.

The second electrode 727 may operate as a cathode. The second electrode 727 may be a transparent electrode or a reflective electrode. When the second electrode 727 is a transparent electrode, the second electrode 727 includes a metal having a low work function, such as, for example, Li, Ca, LiF/Ca, LiF/Al, Al, or Mg, and a compound thereof, and a transparent conductive film including ITO, IZO, ZnO, In₂O₃, which is formed on the metal and the compound thereof. When the second electrode 727 is a reflective electrode, the second electrode 727 includes a metal, such as, for example, Li, Ca, LiF/Ca, AiF/Al, Al, or Mg, and a compound thereof.

According to one embodiment, the first electrode 725 may operate as an anode and the second electrode 727 may operate as a cathode, but alternatively, the first electrode 725 may operate as a cathode and the second electrode 727 may operate as an anode.

According to one embodiment, a plurality of sub-pixels may be formed on the flexible substrate 711, and red, green, blue, or white may be realized per sub-pixel, but embodiments are not limited thereto.

According to one embodiment, the intermediate layer 726 may be commonly formed on the first electrode 725 regardless of a location of a sub-pixel. The organic emission layer may be formed by perpendicularly stacking layers including emission materials emitting red, green, and blue light, or by mixing emission materials emitting red, green, and blue lights.

According to one embodiment, an emission material emitting another color light may be combined as long as a white light is emitted. A color converting layer or a color filter, which converts a white light into a certain color, may be further used.

The encapsulation film 740 may be formed to protect the organic light-emitting display device OLED from external moisture or oxygen. According to one embodiment, the encapsulation film 740 may be formed by alternately stacking at least one inorganic film 741 and at least one organic film 742.

For example, the encapsulation film 740 may have a structure in which the at least one organic film 741 and the at least one organic film 742 are stacked on each other. The inorganic film 741 may include a first inorganic film 743, a second inorganic film 744, and a third inorganic film 745. The organic film 742 may include a first organic film 746 and a second organic film 747.

The inorganic film 741 may include, for example, silicon oxide (SiO2), silicon nitride (SiNx), aluminum oxide (Al2O₃), titanium oxide (TiO2), zirconium oxide (ZrOx), or zinc oxide (ZnO). The organic film 742 may include, for example, PI, PET, PC, polyethylene, or polyacrylate.

The encapsulation film 740 may be formed via a plasma enhanced chemical vapor deposition (PECVD) method.

As described above, according to one or more embodiments, an apparatus for measuring contamination of a plasma generating device may monitor a thickness of a contamination layer on an inner wall of a chamber in real-time during or after plasma processing.

While certain embodiments have been described with reference to the figures, it will be understood by those of ordinary skill in the art that various changes in form and details may be made therein without departing from the spirit and scope as defined by the following claims.

What is claimed is:

1. An apparatus for measuring contamination of a plasma generating device, the apparatus comprising:
a chamber;
a susceptor provided in the chamber and on which a substrate is mounted;
a plasma generator configured to generate plasma in the chamber;
an inner jacket provided in the chamber and surrounding a space where the plasma is generated;
a V-I probe electrically connected to the inner jacket and configured to detect a phase difference between a voltage and a current;
a power supply unit configured to supply the voltage to the inner jacket through a blocking capacitor; and
a monitor connected to the V-I probe and configured to store and display measurement data,
wherein a thickness of a contamination layer on a surface of the inner jacket is determined by analyzing a signal obtained by supplying the voltage to the inner jacket.

2. The apparatus of claim 1, wherein the voltage is supplied from the power supply unit to the inner jacket through the chamber via at least one feedthrough.

3. The apparatus of claim 1, wherein the blocking capacitor is disposed between the power supply unit and the chamber.

4. The apparatus of claim 2, wherein the feedthrough is connected to at least one region of an outer surface of the inner jacket and is configured to monitor a contamination level according to locations thereof in the chamber.

5. The apparatus of claim 1, wherein the inner jacket is spaced apart from an inner wall of the chamber.

6. The apparatus of claim 5, wherein the inner jacket has a wall shape that surrounds the space where the plasma is generated.

7. The apparatus of claim 5, wherein the inner jacket is combined with the chamber, thereby forming a double wall.

8. The apparatus of claim 5, wherein the inner jacket includes a metal.

9. The apparatus of claim 5, wherein the inner jacket comprises a metal layer and an insulating layer coated on an outer surface of the metal layer.

10. The apparatus of claim 5, wherein the inner jacket includes an anodized metal.

11. A method for measuring contamination of a plasma generating device in an apparatus according to claim 1, the method comprising:
generating plasma in the chamber;
supplying the voltage to the inner jacket through a blocking capacitor; and
determining a thickness of the contamination layer on the surface of the inner jacket by analyzing a signal obtained by supplying the voltage to the inner jacket.

12. The method of claim 11, wherein the contamination level of the inner jacket is monitored in real-time.

13. The method of claim 11, wherein the contamination level is monitored without interrupting a vacuum state of the chamber.

14. The method of claim 11, wherein a radio frequency (RF) voltage is supplied to the inner jacket.

15. The method of claim 14, wherein the power supply unit supplies an RF signal in a range from about 1 to about 100 KHz and in a range from about 1 to about 10 V.

16. The method of claim 14, wherein the signal analysis is performed by analyzing a phase difference between the RF voltage and an RF current flowing by the RF voltage, by using the V-I probe.

17. The method of claim 14, wherein the thickness of the contamination layer is calculated based on a capacitance of the contamination layer, wherein the capacitance is calculated based on a phase difference between the RF voltage and an RF current flowing due to the RF voltage.
